(19) United States
(12) Patent Application Publication
(10) Pub. No.: US 2020/0027828 A1
(43) Pub. Date: Jan. 23, 2020

(54) Via-Configurable Memory

(71) Applicant: Intel Corporation, Santa Clara, CA (US)

(72) Inventors: Wayson Lowe, Redwood City, CA (US); Ban Pak Wong, Milpitas, CA (US)

(21) Appl. No.: 16/586,633

(22) Filed: Sep. 27, 2019

(51) Int. Cl. H01L 23/522; G11C 11/412; G11C 11/418; G11C 11/419; G11C 8/16; H01L 27/11

(52) U.S. Cl. CPC H01L 23/5226; G11C 11/412; G11C 11/418; H01L 27/1104; G11C 8/16; H01L 27/1116; G11C 11/419

(57) ABSTRACT

An integrated circuit device includes a memory circuit and a via layer that are used to support different memory demands based on a via configuration of the via layer. A first via configuration of the via layer causes the memory circuit of the integrated circuit device to function as a true dual-port memory circuit in a first via configuration. Moreover, a second via configuration of the via layer causes the memory circuit of the integrated circuit device to function as a simple dual-port memory circuit in a second via configuration.

### BACKGROUND

This disclosure relates to an integrated circuit device used to support different memory demands based on a via configuration of one or more via layers.

This section is intended to introduce the reader to various aspects of art that may be related to various aspects of the present disclosure, which are described and/or claimed below. This discussion is believed to be helpful in providing the reader with background information to facilitate a better understanding of the various aspects of the present disclosure. Accordingly, it should be understood that these statements are to be read in this light, and not as admissions of prior art.

Integrated circuit devices are used in numerous electronic systems. Computers, handheld devices, portable phones, televisions, industrial control systems, robotics, and telecommunication networking devices—to name just a few—may all use integrated circuit devices. Integrated circuit devices may be manufactured using lithography techniques that pattern circuitry onto a substrate wafer. The patterned wafer is then diced to form a number of (generally identical) individual integrated circuit die. An integrated circuit die for a particular application may include many different components, such as programmable logic fabric, digital or analog signal transmission circuitry, digital signal processing circuitry, application-specific data processing circuitry, memory, and so forth. The lithography techniques to form circuits on an integrated circuit die may involve a variety of different steps, possibly including one or more photomasks (e.g., a photomask set) corresponding to that circuitry specific to that integrated circuit die. For example, manufacturing an integrated circuit die that has 1-bit wide write true dual-port memory may involve patterning completely different circuitry using different processes and/or photomask sets as compared to manufacturing an integrated circuit die that has 2-bit wide write true dual-port memory.

### BRIEF DESCRIPTION OF THE DRAWINGS

Various aspects of this disclosure may be better understood upon reading the following detailed description and upon reference to the drawings in which:

FIG. 1 is a block diagram of an integrated circuit device that is programmed with a circuit design, in accordance with an embodiment of the present disclosure;

FIG. 2 is a three-dimensional schematic diagram illustrating multiple layers of the integrated circuit device, including some layers that are the same across several integrated circuit devices, and one or more via layers that may be changed in manufacturing to cause the integrated circuit device to support different applications, in accordance with an embodiment of the present disclosure;

FIG. 3 is a flowchart of a lithography process to fabricate an integrated circuit device, where using a different via layer causes the integrated circuit device to support a different application, in accordance with an embodiment of the present disclosure;

FIG. 4A is a schematic diagram of a via layer with via connections between multiple layers of the integrated circuit device, in accordance with an embodiment of the present disclosure;

FIG. 4B is a three dimensional schematic diagram of the via layer of FIG. 4A, in accordance with an embodiment of the present disclosure;

FIG. 5 is a circuit diagram of a multiplexer of the integrated circuit device, in accordance with an embodiment of the present disclosure;

FIG. 6 is a circuit diagram of the multiplexer of FIG. 5, which may be configured by a via connection of the via layer of the integrated circuit device, in accordance with an embodiment of the present disclosure;

FIG. 7 is a schematic block diagram of a via-configurable static random access memory circuit having different functionality based on a via configuration of a via layer, in accordance with an embodiment of the present disclosure;

FIG. 8 illustrates a schematic diagram of a via configuration (selected via sites) of the via layer to configure the via-configurable static random access memory circuit of FIG. 7 as a 1-bit wide write true dual-port memory, in accordance with an embodiment of the present disclosure;

FIG. 9 illustrates a schematic diagram of a via configuration (selected via sites) of the via layer to configure the via-configurable static random access memory circuit of FIG. 7 as a 2-bit wide write true dual-port memory, in accordance with an embodiment of the present disclosure;

FIG. 10 illustrates a schematic diagram of a via configuration (selected via sites) of the via layer to configure the via-configurable static random access memory circuit of FIG. 7 as a 4-bit wide write true simple dual-port memory, in accordance with an embodiment of the present disclosure;

FIG. 11 illustrates a schematic diagram of a via configuration (selected via sites) of a variation of the via layer to configure the via-configurable static random access memory circuit of FIG. 7 as a 1-bit wide read true dual-port port memory, in accordance with an embodiment of the present disclosure;

FIG. 12 illustrates a schematic diagram of a via configuration (selected via sites) of the variation of the via layer to configure the via-configurable static random access memory circuit of FIG. 7 as a 2-bit wide read true dual-port port memory, in accordance with an embodiment of the present disclosure;

FIG. 13 illustrates a schematic diagram of a via configuration (selected via sites) of the variation of the via layer to configure the via-configurable static random access memory circuit of FIG. 7 as a 4-bit wide read true simple dual-port memory, in accordance with an embodiment of the present disclosure; and

FIG. 14 is a block diagram of a data processing system that may use the integrated circuit device, in accordance with an embodiment of the present disclosure.

### DETAILED DESCRIPTION OF SPECIFIC EMBODIMENTS

One or more specific embodiments will be described below. In an effort to provide a concise description of these embodiments, not all features of an actual implementation are described in the specification. It may be appreciated that in the development of any such actual implementation, as in any engineering or design project, numerous implementation-specific decisions must be made to achieve the developers' specific goals, such as compliance with system-related and business-related constraints, which may vary from one implementation to another. Moreover, it may be appreciated that such a development effort might be complex and time consuming, but would nevertheless be a routine undertaking of design, fabrication, and manufacture for those of ordinary skill having the benefit of this disclosure.

When introducing elements of various embodiments of the present disclosure, the articles “a,” “an,” and “the” are intended to mean that there are one or more of the elements. The terms “comprising,” “including,” and “having” are intended to be inclusive and mean that there may be additional elements other than the listed elements. Additionally, it should be understood that references to “one embodiment” or “an embodiment” of the present disclosure are not intended to be interpreted as excluding the existence of additional embodiments that also incorporate the recited features. Furthermore, the phrase A “based on” B is intended to mean that A is at least partially based on B. Moreover, unless expressly stated otherwise, the term “or” is intended to be inclusive (e.g., logical OR) and not exclusive (e.g., logical XOR). In other words, the phrase A “or” B is intended to mean A, B, or both A and B.

Circuitry of an integrated circuit device may be unique to the specific application for which the integrated circuit device is used. As such, the production of each integrated circuit device for a particular application may unique include additional and/or different fabrication steps, rendering a particular integrated circuit device designed for one application to be become inoperable or ineffective for to perform a different application function. These additional or different fabrication steps may relate to photomasks that are used to pattern circuitry for the specific application functions onto a substrate. Since the circuitry for one application function may be different than the circuitry of a different application function, the photomasks used for each of these circuitry patterns may not be used for both application functions. As will be discussed in more detail, producing the unique circuitry onto a substrate (e.g., wafer) during device fabrication includes the use of lithographic photomasks. Photomasks may be formed using, for example, silica plates with a pattern (e.g., circuit pattern) of opaque and transparent areas that are projected onto the substrate to define the layout of the integrated circuit. In some implementations, a set of photomasks may be used to define one or more pattern layers of a multilayered structure of the integrated circuit. In general, a photomask is placed over the substrate and short wavelength radiation (e.g., short wavelength light) is passed through to project the pattern onto the substrate surface. The patterns may guide the deposit or removal of material from the substrate.

Moreover, integrated circuit devices include multiple layers, and often, these layers are fabricated in a sequential process. Accordingly, each of the multiple layers may be fabricated using a unique photomask or set of photomasks. As such, at least some of the photomask patterns used for a specific circuit design may be not be used for a different circuit design. Producing multiple photomasks for the various integrated circuit devices and/or their multiple layers may have their own respective costs.

To reduce these inefficiencies, this disclosure describes an integrated circuit device that may be manufactured to produce static random access memory (SRAM) circuits that vary in size, such as in width and depth, and/or read and write capabilities, depending on a via configuration of a via layer of the integrated circuit device. Vias are integrated circuit structures that allow circuitry on one layer to form a connection with circuitry on another layer or in another part of the same layer. As used herein, a via configuration defines which potential via sites of a via layer are filled with a material that forms a via, and which potential via sites of the via layer are not. By doing this, different SRAM sizes and read/write capabilities may be implemented without completely separate respective photomasks for the integrated circuit device (e.g., different sets of photomasks for metal layers to route signals). Indeed, rather than include multiple instances of SRAM circuits (e.g., two different sized SRAM circuits used for different application demands and/or located on different dies), fewer circuit elements may be employed that are effectively configured during manufacturing by selecting a photomask or set of photomasks that provides a particular via configuration. In this way, SRAM circuits varying in size and capabilities may be manufactured for different customers.

To that end, it may be desirable to maintain a single integrated circuit architecture with a SRAM block that is configurable to support each of these various sizes and/or read and write capabilities. Moreover, a single SRAM circuit with common circuitry may be used to provide different memory configurations, for example, to meet multiple customers' application specifications. As such, the overall costs of producing multiple photomasks for each circuit and/or multiple integrated circuit layers, for example, for each customer may be mitigated. To implement a via-configurable SRAM circuit in an integrated circuit device that may be configurable for various memory specifications, one or more via layers may be used to connect components and circuitry between the layers of the integrated circuit device. Thus, via openings may be selectively located and formed (e.g., filled or coated with metal) on the via layer to create interconnections between the various components to implement a particular size and/or read and write capabilities for the SRAM circuit in the integrated circuit device. For example, a single SRAM circuit with a via layer may be used to configure the circuitry to implement a true dual-port memory, a simple dual-port memory, and/or various bit width read or write circuits. While this disclosure will primarily use the example of an application-specific integrated circuit (ASIC), the systems and methods of this disclosure may apply to any suitable integrated circuit devices. For example, the methods and devices may be incorporated into numerous types of devices such as microprocessors, system on chip (SoC), or other integrated circuits. Exemplary integrated circuits include programmable array logic (PAL), programmable logic arrays (PLAs), field programmable logic arrays (FPLAs), electrically programmable logic devices (EPLDs), electrically erasable programmable logic devices (EEPLDs), logic cell arrays (LCAs), field programmable gate arrays (FPGAs), application specific standard products (ASSPs), and microprocessors, just to name a few. Moreover, although the following discussions describe a SRAM circuit with one or more via layers, which represents a particular embodiment, it should be noted that the techniques described herein may also be performed and implemented for other memory devices including, but not limited to, various types of dynamic random access memory (DRAM), which represent other embodiments.

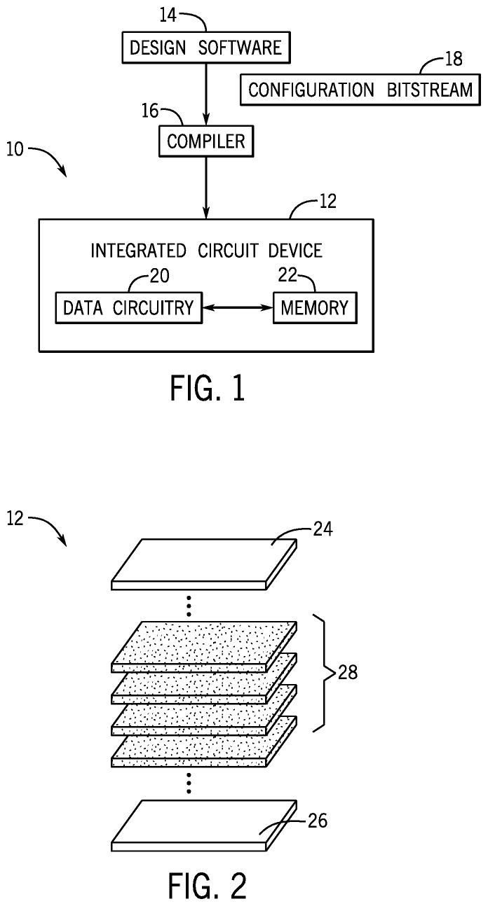

With the foregoing in mind, FIG. 1 illustrates a block diagram of a system 10 that may employ an integrated circuit device 12 on a die that may communicate with on-chip memory or off-chip memory to perform application specific functions. The integrated circuit device 12 may include memory circuitry that may have a different manufactured memory configuration depending on the particular via configuration with which it is manufactured, as will be discussed below with reference to FIGS. 2-13. In the example of FIG. 1, the integrated circuit device 12 includes programmable logic, and thus contains additional circuitry that may be further configured after manufacturing. For example, using the system 10, a designer may implement a specific circuit design functionality on an integrated circuit device 12. In some embodiments, the integrated circuit device 12 may be a programmable integrated circuit, such as a field-programmable gate array (FPGA), that includes one or more programmable fabric dies, which together may implement one or more circuit designs. Each programmable fabric die may also include one or more input/output (I/O) interfaces (e.g., microbumps and/or associated transmission, receiving, driving, and/or routing components) that enable the programmable fabric die to communicate with other devices or components (e.g., internal or external to the integrated circuit device 12).

The designer may implement a circuit design to be programmed onto the integrated circuit device 12 using design software 14, such as a version of Intel® Quartus® by Intel Corporation of Santa Clara, Calif. The design software 14 may use a compiler 16 to generate a low-level circuit-design defined by a configuration bitstream 18, sometimes known as a program object file and/or configuration program that programs the integrated circuit device 12. Thus, the compiler 16 may provide machine-readable instructions representative of the circuit design to the integrated circuit device 12.

For example, the integrated circuit device 12 may receive one or more configuration bitstreams 18 that describe the hardware implementations to be stored in the integrated circuit device 12. Memory specifications, such as size and/or read and write capabilities, may vary based on the number of applications or complexity of applications to be performed by the integrated circuit device 12. A configuration bitstream 18 (e.g., program) may be programmed into the integrated circuit device 12 as a configuration program. To facilitate programming the integrated circuit device 12, the configuration bitstream 18 may be stored in memory 22 and the configuration program may be used to program data circuitry 20. The data circuitry 20 may include programmable logic resources that may be distributed through a number of discrete programmable logic sectors. Each programmable logic sector may include a number of programmable logic elements (e.g., FPGA fabric) having operations defined by configuration memory (e.g., configuration random access memory (CRAM)). The programmable logic elements may include combinational or sequential logic circuitry. For example, the programmable logic elements may include look-up tables, registers, multiplexers, routing wires, and so forth. A designer may program the programmable logic elements to perform a variety of desired functions using the configuration program 18.

The memory 22 that stores the configuration program 18 may be fixed in a read-only memory (ROM) or stored in a writable memory, such as random-access memory (RAM). When the memory 22 is implemented as RAM, the RAM may be written with new routines to implement new operations and functionality into the programmable logic elements and/or sectors. For example, the memory 22 may be distributed (e.g., as random access memory (RAM) cells) throughout various programmable logic sectors of the integrated circuit device 12. The memory 22 may provide a corresponding static control output signal that controls the state of an associated programmable logic element of the interconnection resources of the data circuitry 20. The output signals of the memory 22 may be applied to the gates of metal-oxide-semiconductor (MOS) transistors that control the states of the programmable logic elements of the interconnection resources of the data circuitry 20.

In some implementations, the integrated circuit device 12 may include multiple layers, such that memory 22 and/or memory components are distributed and communicated with across the multiple layers. The memory 22 may be SRAM and, depending on the functionality for which the integrated circuit device 12 is programmed via the configuration bitstream 18, the memory 22 demands may vary. For example, based on application specifications and/or customer memory specifications, the memory 22 size and read/capabilities may be manufactured to vary to facilitate efficient processing of functionalities for which the integrated circuit device 12 is programmed.

To illustrate the integrated circuit device 12 that may be associated with multiple photomasks, FIG. 2 shows a three-dimensional diagram of the integrated circuit device 12 of FIG. 1 with multiple layers of circuitry. As shown, the integrated circuit device 12 may include a first circuit layer 24 and a second circuit layer 26. Although the depicted embodiment illustrates a first circuit layer 24 and a second circuit layer 26, which represents a particular embodiment, it should be noted that the methods and systems described herein may also be performed and implemented for integrated circuit devices 12 having more than two layers (e.g., 4 layers, 18 layers, 24 layers, and so forth).

Circuit components for multiple memory specifications (e.g., varying bit-width read via one port and varying bit-width write via another port) may be attached or embedded into either the first circuit layer 24 and/or the second circuit layer 26 and their electrical connections may be routed on their respective first circuit layer 24 and second circuit layer 26. However, the components used for these specifications are often the same components (e.g., memory cells and multiplexer selections to enable read/write options for the memory cells). For example, an array of memory cells with a particular number of memory cells may be used for a particular memory specification while a smaller number of memory cells may be used for a different memory specification. That is, the smaller number of memory cells may overlap with at least a portion of the entire array of memory cells used for the particular application.

The circuit layers 24 and 26 may be designed to have a variety of possible connections at a variety of possible via sites. Vias are integrated circuit structures that allow circuitry on one layer to form a connection with circuitry on another layer. Depending on the via configuration of one or more via layers 28, the circuit layers 24 and 26 may have different functionalities. Thus, many different memory 22 specifications may be manufactured using the same circuit layers 24 and 26, but the integrated circuit devices 12 may be manufactured to have different memory 22 specifications by selecting a different via configuration for the one or more via layers 28. Although the depicted embodiment illustrates a first circuit layer 24 and a second circuit layer 26, which represents a particular embodiment, it should be noted that the methods and systems described herein may also be performed and implemented for integrated circuit devices 12 having more than two layers (e.g., 4 layers, 18 layers, 24 layers, and so forth). Moreover, one or more via layers 28 may also be disposed to connect to an outer surface for selectively connecting to circuitry in a 2.5D or 3D configuration (e.g., another integrated circuit device 12, an interposer, or Embedded Multi-Die Interconnect Bridge (EMIB) by Intel Corporation®).

The one or more via layers 28 may be manufactured to have a variety of different possible via configurations, where each via configuration provides different connections that determine the functionality of the first circuit layer 24 and the second circuit layer 26, even while the one or more via layers 28 may not be changed. Thus, by manufacturing the one or more via layers 28 using a particular selected photomask or photomask set, a functionality of the circuit layers 24 and 26 may be controlled.

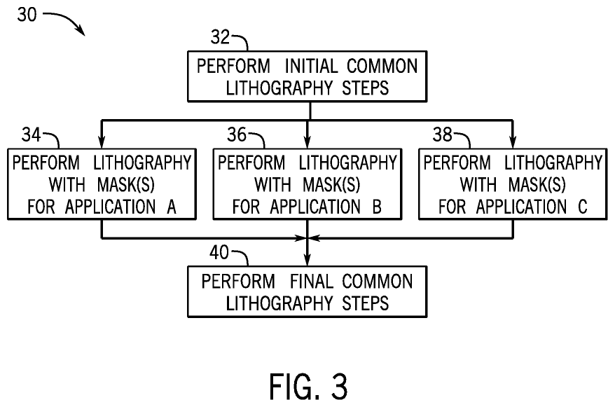

To illustrate, FIG. 3 shows a process flow diagram of process 30 for fabricating an integrated circuit device 12 with a particular via layer that causes the integrated circuit device 12 to selectively provide functionality for one or many different memory applications depending on the via configuration of the via layer. In general, the overall process 30 for fabricating integrated circuit devices 12 for each particular application includes steps of depositing, patterning, removing, and modifying electrical properties. As shown, the process 30 may begin with performing (block 32) initial common lithography steps. These steps may include the depositing process, which includes coating or transferring photoresist material (e.g., liquid polymeric material or dry film photoresists) onto a substrate, such as a wafer. The photoresist is material that the image may be transferred to during the patterning process.

Next, the patterning step may include fabricating pattern from a photomask onto the wafer by exposing the wafer to light using the photomask. As previously discussed, photomasks are often formed from silica plates with a pattern, such as a circuit pattern, of opaque and transparent areas that are projected onto the wafer to define the layout of the integrated circuit. In some implementations, a set of photomasks may be used to define one or more pattern layers of the multilayered structure of the integrated circuit device 12. In general, the photomask is placed over the substrate and a short wavelength light is passed through to project the pattern onto the substrate surface.

While the common lithography steps of block 32 are common to all versions of the integrated circuit device 12 that are manufactured using the process 30, different versions of the integrated circuit device 12 may have different application functionalities and memory specifications based on the functionalities (e.g., shown by way of example here as Application A, Application B, and Application C, but it should be appreciated that any suitable number of different applications may be supported). That is, memory 22 configurations may vary based on a specific application demand, customer design specifications, and so forth.

Thus, the process 30 may also include performing (block 34) lithography with mask(s) for Application A (e.g., a 20-bit wide true dual-port memory circuit) that produces one or more via layers that will form connections that cause the circuitry formed at block 32 to operate with a first functionality (e.g., as a 20-bit wide true dual-port memory). On the other hand, the process 30 may include performing (block 36) lithography with mask(s) for Application B (e.g., a 40-bit wide true dual-port memory circuit) that produces one or more via layers that will form connections that cause the circuitry formed at block 32 to operate with a second functionality (e.g., as a 20-bit wide true dual-port memory). Further, the process 30 may include performing (block 38) lithography with mask(s) for Application C (e.g., an 80-bit wide simple dual-port memory circuit) that produces via layers that will form connections that cause the circuitry formed at block 32 to operate with a third functionality (e.g., as an 80-bit wide simple dual-port memory). Specifically, performing lithography for each of these applications may include selecting via sites of the common via layers to configure for either the integrated circuit device 12 for Application A, Application B, or Application C. Thus, the one or more via layer photomasks or photomasks sets are used to pattern and selectively connect components for each of the different integrated circuit devices 12 (e.g., integrated circuits for each application A, B, and C) that may be manufactured by the process 30.

The process 30 may include performing (block 40) the certain final common lithography steps. The final common steps may include steps related to the removal of coating and modification of electrical properties.

The location of the multiple via sites or openings may be based on the various possible application functions to be performed and the components used to perform such functions. The selectable via sites may be filled (e.g., configured or selected) or remain unfilled (e.g., not selected) depending on the memory specifications to be implemented for a given application. Thus, when the via layer is configured for Application A by selecting particular via sites that connect the components (e.g., memory cells) corresponding to perform Application A, there may be via sites that remain unselected since the components connected to those via sites (e.g., additional memory cells) may not be used to perform the functions of Application A. Similarly, some of the via sites used to perform Application A may not be selected when the via layer is configured for Application B. As such, using a lithography process for each particular application (e.g., Applications A, B, and C) may be mitigated or avoided by using a configurable via layer. Thus, fewer photomasks and/or application specific integrated circuit devices 12 may be manufactured, resulting in lower manufacturing costs and more efficient integrated circuit devices 12. Upon configuring the via layer for the particular application, such as by selecting particular vias (e.g., filling via openings with metal) to interconnect components used for the particular application, the integrated circuit, or at least those vias selected, may have a static configuration.

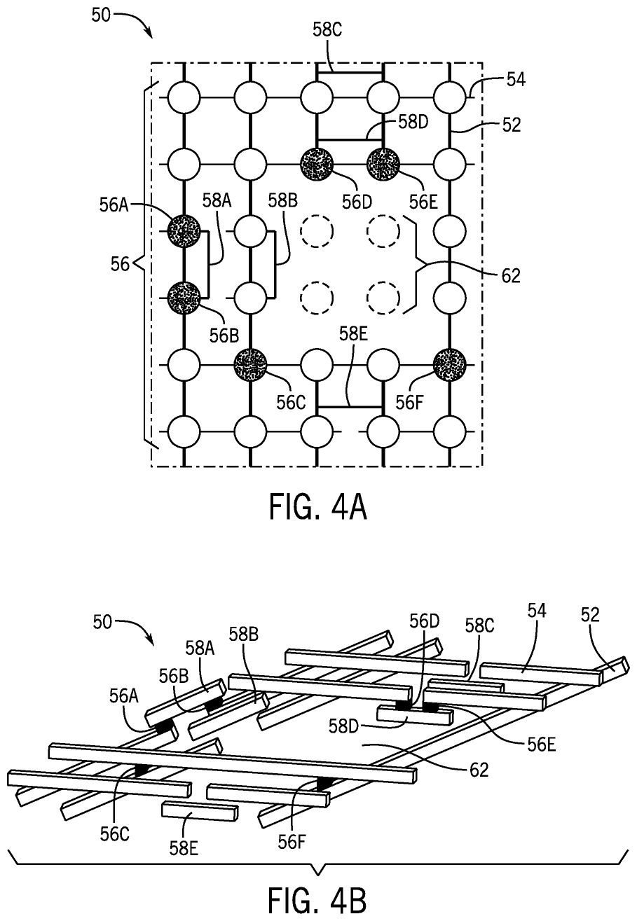

As previously mentioned, to facilitate the reuse of circuitry or components between the layers of the single integrated circuit device 12 to implement different applications, vias may be used. For example, and referring back to Applications A and B, some of the circuitry components, such as a portion of memory cells and/or memory configuration components, that are used for Application A may also be used for the circuitry for Application B. Thus, these circuitry components may be reused when the via layer is configured for either Application A or Application B. To illustrate, FIG. 4A, which represents a particular embodiment, depicts an integrated circuit device 12 with a via layer 50 (e.g., one or more via layers 28 of FIG. 2) including selectable via sites 56 that may connect components and/or circuitry residing on different layers (e.g., the first circuit layer 24 and the second circuit layer 26 of FIG. 2) of the integrated circuit device 12. Although the following discussions describe the integrated circuit device 12 as having two via layers 50 in the depicted embodiment, it should be appreciated that one or more via layers 50 (e.g., one, four, six, and so forth) may be used to implement different applications or functions using the vias connections described herein. The additional via layers 50 may be used to connect components between the one or more layers.

As shown, the via layer 50 may include a vertical segment layer 52 (as indicated by the vertical bold lines) of metal segments and a horizontal segment layer 54 (as indicated by the horizontal and relatively thinner lines) of metal segments. The vertical segment layer 52 and the horizontal segment layer 54 may each include selectable via sites 56, which may be used to interconnect segments of the vertical and horizontal segment layers 52 and 54. In some implementations, jumpers 58 may be selectively placed vertically or horizontally along the segments of the vertical segment layer 52 and the horizontal segment layer 54 to facilitate vias connections that may otherwise be disconnected. For example, the jumpers 58 may facilitate in connecting or disconnecting via sites 56 to connect or disconnect segments. As such, the via layer 50 may also be configured using the jumpers 58. The circuitry components on the first circuit layer 24 and the second circuit layer 26 that are connected to a respective segment of the via layer 50 (e.g., vertical segment layer 52 and the horizontal segment layer 54) may be connected or disconnected using the via sites 56 to form a circuit for a particular application.

To illustrate, selected vias (e.g., via sites filled with metal to create interconnection) are indicated by darkened selectable via sites 56 in the depicted embodiments. As shown, jumpers 58A, B, C, D, and E create a link between selectable via sites 56 that are on the same segment layer. For example, selectable via sites 56A and 56B may reside on separate segments of the vertical segment layer 52. Accordingly, jumper 58A may connect these two segments, such that when the selectable via sites 56A and 56B are selected, components and/or circuitry on their respective segments may be connected. Similarly, jumpers 58B, 58C, 58D, and 58E may connect selectable via sites 56, such that the jumpers 58 allow a connection to be made between segments of the vertical segment layer 52 or the horizontal segment layer 54, and between the vertical segment layer 52 and the horizontal segment layer 54 when their respective selectable via sites 56 are selected.

Although jumpers 58 may be placed between segments of the vertical segment layer 52 and the horizontal segment layer 54, some of the selectable via sites 56 may not be selected, as indicated by the white selectable via sites 56. In such instances, segments of vertical segment layer 52 and the horizontal segment layer 54 may not be connected. For example, jumper 58E may connect two segments of the horizontal segment layer 54 when the selectable via sites 56 are selected. Since these selectable via sites 56 are not selected, the segments may not be connected and thus, the components or circuitry on those segments may not be interconnected. Moreover, in some implementations, non-selectable via sites 62 may exist on the vertical segment layer 52 and/or the horizontal segment layer 54. The non-selectable via sites 62 may include areas that may not be suitable for a selectable via site 56. These areas may not be adjacent or parallel to components on the other layers, may include jumper connections, or that may include base circuitry or application specific circuitry that is not compatible for use for a different application.

To further illustrate the connections between the layers 52 and 54 using jumpers 58 and/or selectable via sites 56, FIG. 4B depicts a three dimensional (3-D) diagram of the via layer 50 of FIG. 4A. As shown, segments of the vertical segment layer 52 and the horizontal segment layer 54 may be connected using jumpers 58 and selectable via sites 56 connections that correspond to FIG. 4A. For example, selectable via sites 56A and 56B may reside on separate segments of the first layer 52. Accordingly, jumper 58A may connect these two segments, such that when the selectable via sites 56A and 56B are selected, components and/or circuitry on their respective layer segments may be connected. Also corresponding to FIG. 2, jumpers 58B, 58C, 58D, and 58E may connect selectable via sites 56, such that jumpers 58 allow a connection to be made between segments of the vertical segment layer 52 and the horizontal segment layer 54, and between the vertical segment layer 52 and horizontal segment layer 54 when their respective selectable via sites 56 are selected. These segments of layers 52 and 54 may include components or circuitry that may be connected to perform specific functions.

Specifically, the selectable via sites 56 that are selected may be active sites used to short the path between the vertical segment layer 52 and the horizontal segment layer 54. In this manner, the components on the portion of the layer connected to the via site 56 may be used or unused depending on the selection of the selectable via site 56. Thus, using vias may reduce the number of application specific circuits and layers, and correspondingly, reduce the number of photomasks used to produce each of the layers. By way of example, the integrated circuit device 12 may include Moreover, since circuit components between layers of the integrated circuit device 12 may be reused, vias may reduce the amount of circuitry and silicon area that may otherwise be used for each application.

As previously discussed, the integrated circuit device 12 may include memory 22, which may vary in size and depth depending on the demands for the application functionality of the integrated circuit device 12. For example, based on the particular application demands, the size of the memory 22 may be a 20-bit wide memory configuration, a 40-bit wide memory configuration, a 80-bit wide memory configuration, and so forth, and each may be formed using separate photomasks. However, these memory size configurations may include common components. As will be described herein, rather than forming separate memory circuits, the single via layer 50 may be used to connect the redundant components (e.g., memory cells and multiplexers) of circuitry between layers of the integrated circuit device 12 to configure circuitry and implement the specific memory configuration for the integrated circuit device 12. As used herein, redundant components may refer to one or more common components to the circuit resulting from a first configuration, such as 20-bit wide true dual-port memory, and the circuit resulting from a different configuration, such as a 40-bit wide simple dual-port memory. Additionally or alternatively to selectable via sites 56, multiplexers may be used to configure and select specific circuitry to implement any of the driver circuit standards.

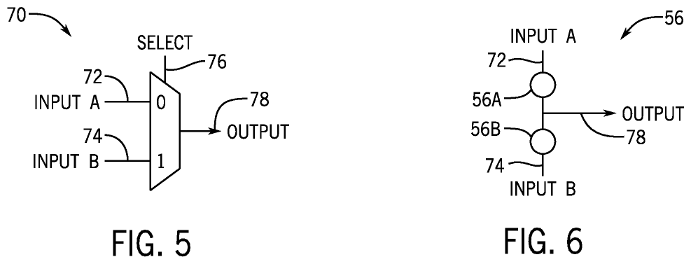

To illustrate, FIG. 5 depicts a multiplexer 70 that may be configured and programmed to select a memory size and functionality. As shown, the multiplexer 70 may include two input ports, input A 72 and input B 74, one control select signal, select 76, and an output port, output 78. A control select signal at select 76 may be used to control which input port (e.g., input A 72 or input B 74) is utilized to select a bit lines that are driven to implement a read port, a write port, and/or a bit width. For example, input A 72 may be used for the output 78 when the control signal at select 76 has a value of “0.” On the other hand, input B 74 may be used for the output 78 when the control signal at select 76 has a value of “1.” Thus, to implement a particular bit width size, a particular bit depth size, implement a particular port as a read port, and/or implementing a particular port as a write port, input A 72 or input B 74 may be selectively enabled using select 76.

In other embodiments, vias may be used in conjunction with or in place of multiplexer 70 of FIG. 5. To illustrate, FIG. 6 depicts a static configuration of via sites 56 (e.g., selectable via sites 56 of FIG. 4A) that may be selected (e.g., via openings filled with metal to create interconnection) to implement a particular application. As shown, the via site 56A may connect an input A 72 to output an output 78 when selected, or via site 56B may connect an input B 74 to output a different result of output 78 when selected. Circuitry and components of input A 72 connected to via site 56A may be enabled for use upon selection of the via site 56A. Similarly, circuitry or components of input B 74 that are connected to via site 56B, may be enabled for use upon selection or activation of the via site 56B.

Thus, by selecting particular via sites 56A or 56B, the circuitry of the selected inputs (e.g., input A 72 or input B 74) may be included in the integrated circuit device 12 to be used for the particular memory configuration. Via sites 56 may be selected or unselected (e.g., remain unfilled) based on the application to be executed and the circuitry used for the particular application. As such, at least some circuitry components that are connected for a particular via configuration may be unused in a different via configuration. As previously mentioned, via sites 56 of the via layer 50 may be selected to configure the integrated circuit device 12 by connecting redundant circuitry between the various layers of the integrated circuit device 12. In this manner, producing additional mask layers associated with each application specific integrated circuit device 12 and/or circuitry for a particular application of the integrated circuit device 12 may be mitigated.

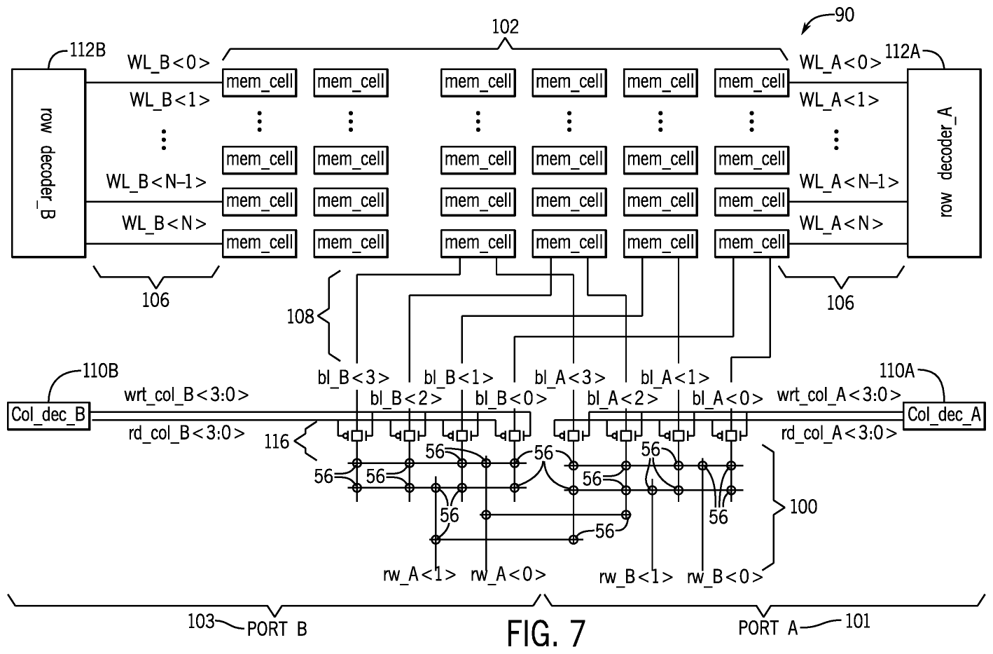

To illustrate, FIG. 7 shows a dual-port static random access memory circuit 90 with a via layer 100 (e.g., which may be formed using one or more via layers 28 as shown in FIG. 2) used to configure the static random access memory circuit 90. The memory circuit 90 may include an array of horizontal rows and vertical columns of memory cells 102. Each of the memory cells 102 may store one bit (e.g., 0 or 1). To access a particular memory cell, such as for a read operation or a write operation, a respective word line 106 and a respective bit line 108 may be activated (e.g., selected) according to an address. During a write operation, input data may be stored in the memory cells 102. During a read operation, output data may be transmitted from the memory cells 102 and held.

To activate the word line 106 and bit line 108, decoders may be used. Specifically, a column decoder, such as column decoder A 110A (col_dec_A) for port A 101 and column decoder B 110B (col_dec_B) for port B 103 may be used to select bit lines 108 corresponding to a targeted column of memory cells 102 based on a corresponding column memory address. Similarly, a row decoder, such as row decoder A 112A (row decoder_A) for port A 101 and a row decoder B 112B (row decoder_B) for port B 103 may be used to select a word line 106 corresponding to a targeted row of memory cells 102. For example, the word lines 106 may correspond to respective ports, such as port A 101 (e.g., word lines WL_A<0> to WL_A<N>) and port B 103 (e.g., word lines WL_B<0> to WL_B<N>).

Port A 101 and Port B 103 may each be used for read and/or write functionalities. By way of example, port A 101 may be configured as a read port while port B 103 may be configured as a write port. As such, to write to the memory circuit 90, data may be sent via bit lines 108 of port B 103. Although the depicted embodiment shows 4 bit lines 108 for port A 101 (e.g., bl_A<0> to bl_A<3>) and four bit lines 108 for port B 103 (e.g., bl_B<0> to bl_B<3>), which represents a particular embodiment, the techniques described herein may include fewer or greater number of bit lines 108 to send data to or receive data from the memory cells 102.

Upon selecting the targeted memory cells 102 in a row via the row decoders 112, the data from the respective memory cells 102 may be sent or received by transistors 116 (e.g., forming a multiplexer) over bit lines 108 to respective port A 101 and port B 103. For example, the bit lines 108 may connect to transistors 116 of each of the ports. For example, inputs to and outputs from port A 101 may connect to memory cells 102 via a first transistor 116A that connects to a first bit line 108A, a second transistor 116B that connects to a second bit line 108B, a third transistor 116C that connects to a third bit line 108C, and a fourth transistor 116D that connects to a fourth bit line 108D (bl_A<0> to bl_A<4>). Similarly, inputs to and outputs from port B 103 may connect to memory cells 102 via a fifth bit line 108E, a sixth bit line 108F, a seventh bit line 108G, and an eighth bit line 108H (bl_B<0> to bl_B<4>).

The column decoders 110 may control the transistors 116, for example, by decoding a column memory address. Decoding the memory address may allow the decoders 110 to switch the transistors 116 to ON or OFF, which allows selecting bit lines 108 connected to the transistors 116. Upon decoding, the transistors 116 input and/or output the respective bits to and/or from the bit lines 108. By way of example, the row decoders 112 may select a row of memory cells 102 based on decoding a row memory address. The column decoders 110 may decode a column memory address to read values from or write values to particular memory cells 102 of the selected row by selecting transistors 116 tied to the particular memory cells 102 via bit lines 108.

Moreover, the transistors 116 may also be selected to configure the memory cells 102 for different memory specifications. That is, the transistors 116 may enable the memory circuit 90 to be configured for various sized memory 22 and/or read and write capabilities. As previously mentioned, the redundant components of the memory circuit 90 (e.g., memory cells 102, row decoders 112, column decoders 110, transistors 116, bit lines 108, word lines 106, and so forth) on different layers (e.g., the first circuit layer 24 and the second circuit layer 26 of FIG. 2) of the integrated circuit device 12 may be used to provide such configurations. Moreover, the via layer 100 may be used to enable connections between the components on the different layers to provide the specific memory configurations. Specifically, the via layer 100 may be configured to support the different memory specifications by selecting via sites 56 that are connected to the transistors 116, and in extension, the bit lines 108 when the respective transistors 116 are ON or OFF for a decoded value. Additionally, while the via sites 56 connect common components to implement the different memory specifications, at least a portion of the memory circuit 90 may not be used in some embodiments.

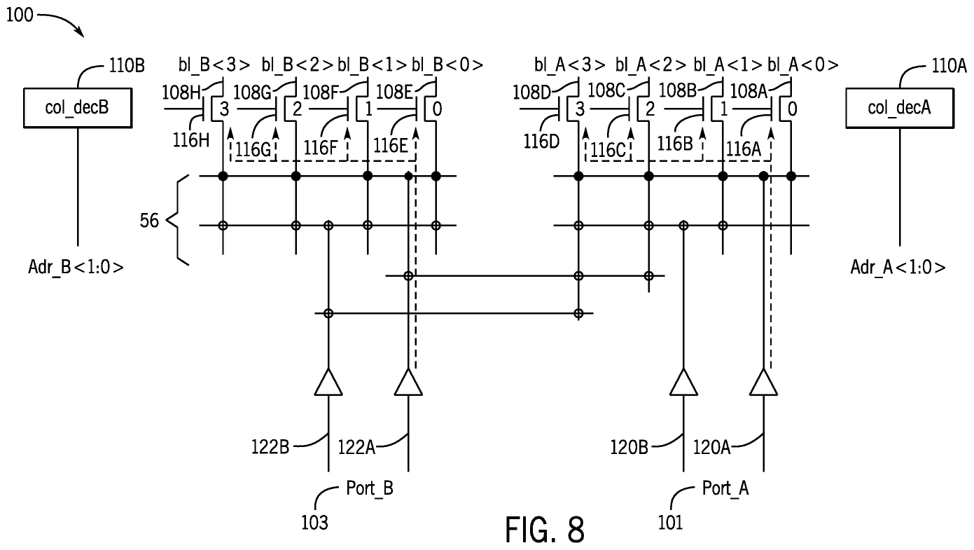

To illustrate, FIG. 8 depicts selection of via sites 56 of the via layer 100 to configure the via-configurable static random access memory circuit 90 of FIG. 7 as a 1-bit wide write true dual-port memory. Briefly, a simple dual-port memory includes two ports in which write access to the memory circuit 90 may be permitted through one port (e.g., port A 101) while the read access may be permitted through the other port (e.g., port B 103). On the other hand, a true dual-port memory includes two ports in which read access and write access to the memory circuit 90 is permitted through either port (e.g., port A 101 and port B 103).

Port A 101 and port B 103 may each include four transistors 116 that are connected to four bit lines 108, such that if each transistors 116 is ON and respective via sites 56 of via paths connecting to transistors 116 are selected, an 8-bit width read or write may be implemented. For example, transistors 116 may be enabled and/or disabled to input or output data, to or from their respective bit lines 108 (connected to the memory cells 102).

In the depicted embodiment, the column decoder A 110A may decode either a value (e.g., a column memory address) of 0, 1, 2, or 3. Upon decoding either of these values, the bit lines 108 connected to the respective transistor 116, such as a first transistor 116A, a second transistor 116B, a third transistor 116C, or a fourth transistor 116D, may write data to the memory cells 102 connected to the respective bit line 108. Similarly, the column decoder B 110B may decode either a value of 0, 1, 2, or 3. Upon decoding either of these values, the bit lines 108 connected to the respective transistor 116, such as a fifth transistor 116E, a sixth transistor 116F, a seventh transistor 116G, or the eighth transistor 116H, may write data to their respective memory cells 102.

The inputs to write data may include a first port A input 120A, a second port A input 120B, a first port B input 122A, and a second port B input 122B. However, the selected via sites 56 (indicated by darkened via sites 56) create a via path (indicated by dashed arrows) that enable only the first port A input 120A to write via port A 101 and the first port B input 122A to write via port B 103. That is, the first port A input 120A may write data via the first transistor 116A, the second transistor 116B, the third transistor 116C, or the fourth transistor 116D. Since the column decoder A 110A decodes one value at a time (based on the column memory address), such as either the 0, 1, 2, or 3, the first port A input 120A may only write one value at a time.

Similarly, the first port B input 122A may write data via the fifth transistor 116E, the sixth transistor 116F, the seventh transistor 116G, or the eighth transistor 116H. Since the column decoder B 110B decodes one binary value at a time, such as either the 0, 1, 2, or 3, the first port B input 122A may also only write one value at a time. Thus, the selection of via sites 56 in the depicted embodiment may configure the memory circuit 90 as a 1-bit width write memory. Moreover, since either inputs from port A 101 or port B 103 may write to the memory circuit 90, the selection of via sites 56 in the depicted embodiment may configure the memory circuit 90 as a true dual-port memory. As such, the selection of via sites 56 in the depicted embodiment may configure the memory circuit 90 as a 1-bit width write true dual-port memory.

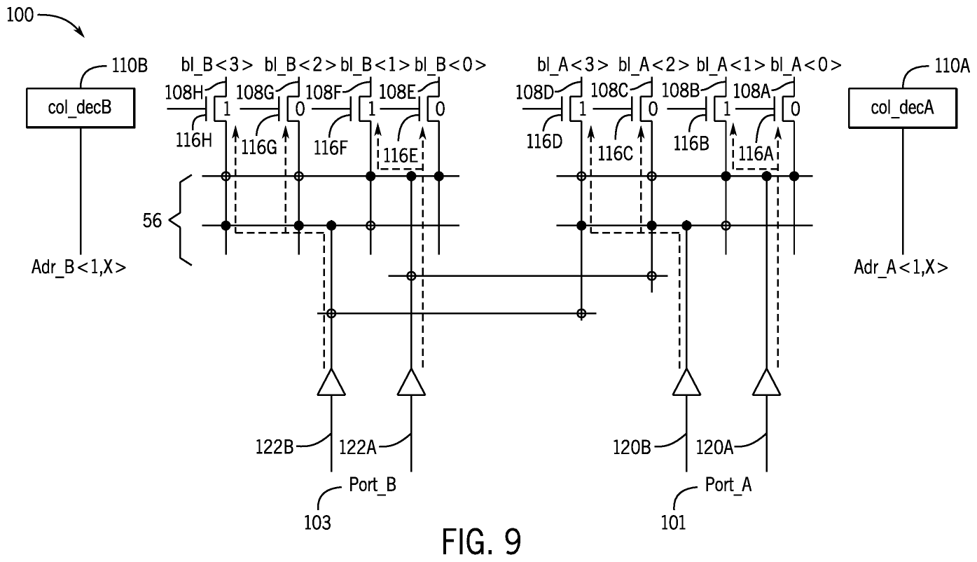

FIG. 9 depicts selection of via sites 56 of the via layer 100 to configure the via-configurable static random access memory circuit 90 of FIG. 7 as a 2-bit wide write true dual-port memory. In the depicted embodiment, the column decoder A 110A may decode either a value (e.g., column memory address) of 0 or 1. Upon decoding either of these values, the bit lines 108 connected to the respective transistor 116 for the decoded value (e.g., 0 or 1) may write data to the memory cells 102 connected to the respective bit lines 108. As shown, the first transistor 116A and third transistor 116C may correspond to a decoded value of 0. The second transistor 116B and the fourth transistor 116D may correspond to a decoded value of 1.

Similarly, the column decoder B 110B may decode either a value (e.g., memory address) of 0 or 1. Upon decoding either of these values, the bit lines 108 connected to the respective transistor 116 for the decoded value may write data to the memory cells 102 connected to the respective bit lines 108. As shown, the fifth transistor 116E and the seventh transistor 116G may correspond to a decoded value of 0. The sixth transistor 116F and the eighth transistor 116H may correspond to a decoded value of 1. Thus, when the column decoder B 110B decodes a binary 0, two transistors may write data to the memory cells 102 (e.g., via the fifth transistor 116E and the seventh transistor 116G).

The inputs to write data may include a first port A input 120A, a second port A input 120B, a first port B input 122A, and a second port B input 122B. The selected via sites 56 (indicated by darkened via sites 56) create a via path (indicated by dashed arrows) that enables the first port A input 120A to write via the first transistor 116A or the second transistor 116B for port A. Moreover, the via selected via sites 56 create a path that enables the second port A input 120B to write via the third transistor 116C or the fourth transistor 116D. Since the column decoders A 110A decodes one binary value (e.g., column memory address) at a time, such as either the 0 or the 1, port A 101 may be used to write two inputs at a time. That is, when the column decoder A 110A decodes a 0, the first port A input 120A may write to the memory circuit 90 via the first transistor 116A and the second port A input 120B may write to the memory circuit 90 via the third transistor 116C. On the other hand, when the column decoder A 110A decodes a 1, the first port A input 120A may write to the memory circuit 90 via the second transistor 116B and the second port A input 120B may write to the memory circuit 90 via the fourth transistor 116D.

Similarly, the selected via sites 56 (indicated by darkened via sites) create a via path (indicated by dashed arrows) that enables the first port B input 122A to write via the fifth transistor 116E or the sixth transistor 116F for port B. Moreover, the via selected via sites 56 create a path that enables the second port B input 122B to write via the seventh transistor 116G or the eighth transistor 116H. Since the column decoder B 110B decodes one binary value (e.g., column memory address) at a time, such as either the 0 or the 1, port A 101 may be used to write two inputs at a time. That is, when the column decoder B 110B decodes a 0, the first port B input 122A may write to the memory circuit 90 via the fifth transistor 116E and the second port B input 122B may write to the memory circuit 90 via the seventh transistor 116G. On the other hand, when the column decoder B 110B decodes a 1, the first port B input 122A may write to the memory circuit 90 via the sixth transistor 116F and the second port B input 122B may write to the memory circuit 90 via the eighth transistor 116H. Thus, the selection of via sites 56 in the depicted embodiment may configure the memory circuit 90 as a 2-bit width write memory. Moreover, since either inputs from port A 101 or port B 103 may write to the memory circuit 90, the selection of via sites 56 in the depicted embodiment may configure the memory circuit 90 as a true dual-port memory. As such, the selection of via sites 56 in the depicted embodiment may configure the memory circuit 90 as a 2-bit width write true dual-port memory.

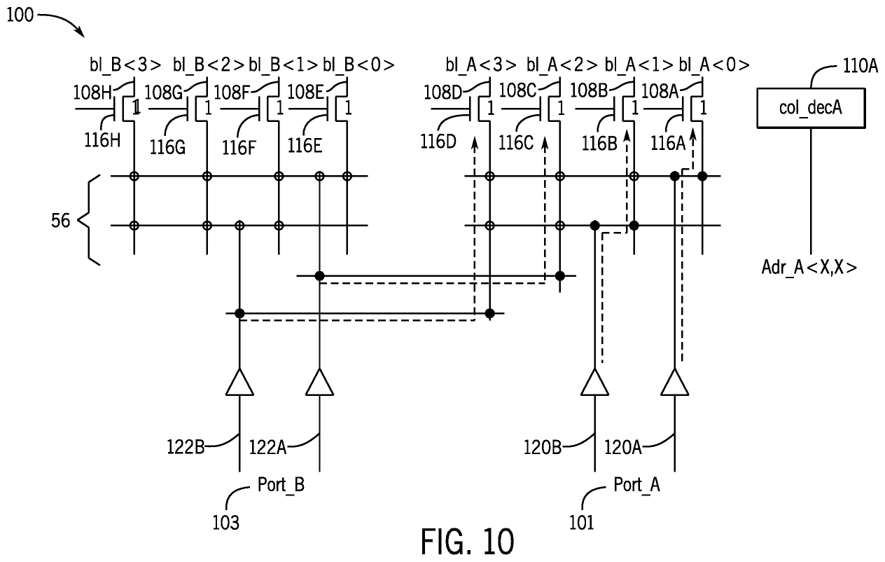

FIG. 10 depicts selection of via sites 56 of the via layer 100 to configure the via-configurable static random access memory circuit 90 of FIG. 7 as a 4-bit wide write simple dual-port memory. In the depicted embodiment, the column decoder A 110A may decode a value (e.g., column memory address) of 1. Upon decoding a 1, the bit lines 108 connected to the respective transistor 116 for the decoded value of 1 may write data to the memory cells 102 connected to the respective bit lines 108. As shown, the first transistor 116A, the second transistor 116B, the third transistor 116C, and the fourth transistor 116D, may correspond to a decoded value of 1. Thus, when the column decoder A 110A decodes a binary 1, four transistors may be enabled to write to the memory circuit 90 through port A 101. As such, the depicted embodiment may result in a 4-bit width write memory.

The inputs to write data may include a first port A input 120A, a second port A input 120B, a first port B input 122A, and a second port B input 122B. The selected via sites 56 (indicated by darkened via sites 56) create a via path (indicated by the dashed arrows) that enables the first port A input 120A to write via the first transistor 116A and the second port A input 120B to write via the second transistor 116B. Moreover, the selected via sites 56 create a path that enables the first port B input 122A to write via the third transistor 116C and the second port B input 122B to write via the fourth transistor 116D. Since the column decoders A 110 decodes one binary value at a time, such as binary 1, port A 101 may write four inputs at a time. That is, when the column decoder A 110A decodes a 1, the port A inputs 120 and the port B inputs 122 may write to their respective transistor 116.

Moreover, since only inputs sent from port A 101 may write to the memory circuit 90, the selection of via sites 56 in the depicted embodiment may configure the memory circuit 90 as a simple dual-port memory. As such, the selection of via sites 56 in the depicted embodiment may configure the memory circuit 90 as a 4-bit width write simple dual-port memory (using four bit lines 108A-D).

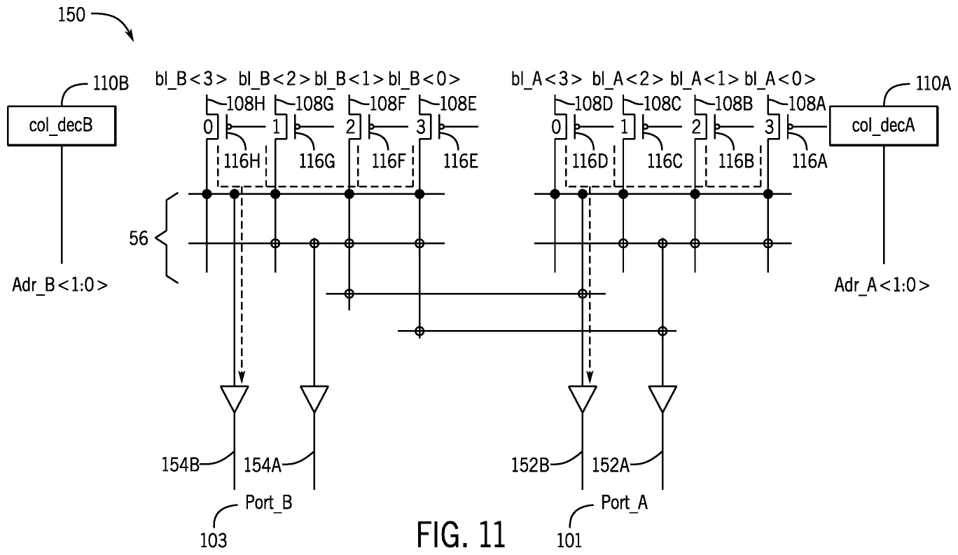

FIG. 11 depicts selection of via sites 56 of a via layer 150 (e.g., a variation of via layer 100) to configure the via-configurable static random access memory circuit 90 of FIG. 7 as a 1-bit wide read true dual-port memory. As previously mentioned, a simple dual-port memory includes two ports in which write access to the memory circuit 90 is permitted through one port (e.g., port A 101) while the read access is permitted through the other port (e.g., port B 103). On the other hand, a true dual-port memory includes two ports in which read access and write access to the memory circuit 90 is permitted through either port (e.g., port A 101 and port B 103).

Port A 101 and port B 103 may each include four transistors 116 that are connected to four bit lines 108, such that if each transistors 116 is ON and respective via sites 56 of via paths connecting to transistors 116 are selected, an 8-bit width read or write may be implemented. For example, transistors 116 may be selected or enabled to input or output data, to or from their respective bit lines 108 (connected to the memory cells 102).

In the depicted embodiment, the column decoder A 110A may decode either a value (e.g., column memory address) of 0, 1, 2, or 3. Upon decoding either of these values, the bit lines 108 (e.g., bit lines bl_A_0 through bl_A_3) connected to the respective transistor 116, such as a first transistor 116A, a second transistor 116B, a third transistor 116C, or a fourth transistor D, may read data from the memory cells 102 connected to the bit line 108. Similarly, the column decoder B 110B may decode either a value of 0, 1, 2, or 3. Upon decoding either of these values, the bit lines 108 connected to the respective transistor 116, such as a fifth transistor 116E, a sixth transistor 116F, a seventh transistor 116G, or the eighth transistor 116H, may read data from the memory cells 102 connected to the respective bit lines 108.

The outputs to data read may include a first port A output 152A, a second port A output 152B, a first port B output 154A, and a second port B output 154B. However, the selected via sites 56 (indicated by darkened via sites 56) create a via path (indicated by dashed arrows) that enables only the second port A output 152B to read from port A 101 and the second port B output 154B to read from port B 103. That is, the second port A output 152B may read data via the first transistor 116A, the second transistor 116B, the third transistor 116C, or the fourth transistor 116D. Since the column decoder A 110A decodes one binary value at a time, such as either the 0, 1, 2, or 3, port A 101 may be used to read only one output at a time.

Similarly, the second port B output 154B may read data via the fifth transistor 116E, the sixth transistor 116F, the seventh transistor 116G, or the eighth transistor 116H. Since the column decoder B 110B decodes (e.g., column memory address) one binary value at a time, such as either the 0, 1, 2, or 3, port B 103 may also only read one value at a time. Thus, the selection of via sites 56 in the depicted embodiment may configure the memory circuit 90 as a 1-bit width write memory. Moreover, since either outputs from port A 101 or port B 103 may read from the memory circuit 90 (e.g., via transistors 116 connected to bit lines 108), the selection of via sites 56 in the depicted embodiment may configure the memory circuit 90 as a true dual-port memory. As such, the selection of via sites 56 in the depicted embodiment may configure the memory circuit 90 as a 1-bit width read true dual-port memory.

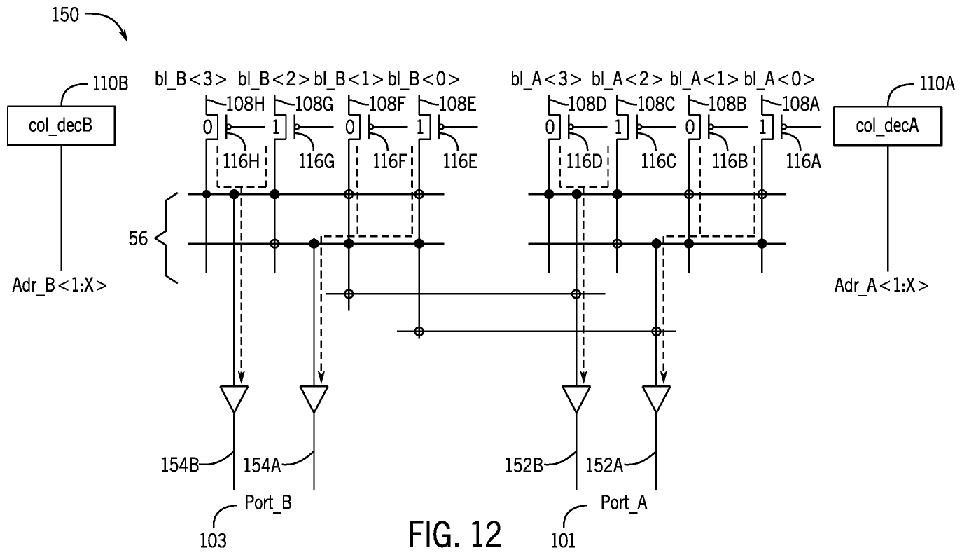

FIG. 12 depicts selection of via sites 56 of the via layer 150 to configure the via-configurable static random access memory circuit 90 of FIG. 7 as a 2-bit wide read true dual-port memory. In the depicted embodiment, the column decoder A 110A may decode either a value (e.g., column memory address) of 0 or 1. Upon decoding either of these values, the bit lines 108 connected to the respective transistor 116 for the decoded value (e.g., 0 or 1) may enable reading from the memory cells 102 connected to the respective bit lines 108. As shown, the first transistor 116A and third transistor 116C may correspond to a decoded value of 1. The second transistor 116B and the fourth transistor 116D may correspond to a decoded value of 0.

Similarly, the column decoder B 110B may decode either a value of 0 or 1. Upon decoding either of these values, the bit lines 108 connected to the respective transistor 116 for the decoded value may enable reading from the memory cells 102 connected to the respective bit lines 108. As shown, the fifth transistor 116E and the seventh transistor 116G may correspond to a decoded value of 1. The sixth transistor 116F and the eighth transistor 116H may correspond to a decoded value of 0. Thus, when the column decoder 110 decodes a binary 1, two transistors may read from the respective bit lines 108 (e.g., memory circuit 90). Similarly, when the column decoder B 110B decodes a binary 0, two transistors 116 may read from the respective bit lines 108 (e.g., memory circuit 90). As such, the depicted embodiment may result in a 2-bit width write memory.

The inputs to read data may include a first port A output 152A, a second port A output 152B, a first port B output 154A, and a second port B output 154B. The selected via sites 56 (indicated by darkened via sites 56) create a via path (indicated by dashed arrows) that enables the first port A output 152A to read via the first transistor 116A or the second transistor 116B for port A. Moreover, the via selected via sites 56 create a path that enables the second port A output 154B to read via the third transistor 116C or the fourth transistor 116D. Since the column decoders A 110A decodes one binary value (e.g., column memory address) at a time, such as either the 0 or the 1, port A 101 may read two outputs at a time. That is, when the column decoder A 110A decodes a 1, the first port A output 152A may read from the memory circuit 90 via the first transistor 116A and connected bit lines 108, and the second port A output 152B may read from the memory circuit 90 via the third transistor 116C. On the other hand, when the column decoder A 110A decodes a 0, the first port A output 152A may read from memory circuit 90 via the second transistor 116B and the second port A output 152B may read from the memory circuit 90 via the fourth transistor 116D.

Similarly, the selected via sites 56 create a via path that enables the first port B output 154A to read via the fifth transistor 116E or the sixth transistor 116F for port B 103. Moreover, the via selected via sites 56 create a path that enables the second port B output 154B to read via the seventh transistor 116G or the eighth transistor 116H. Since the column decoder B 110B decodes one binary value (e.g., column memory address) at a time, such as either the 0 or the 1, port B 103 may read two outputs at a time. Thus, the selection of via sites 56 in the depicted embodiment may configure the memory circuit 90 as a 2-bit width write memory. That is, when the column decoder B 110B decodes a 1, the first port B output 154A may read from the memory circuit 90 via the fifth transistor 116E and the second port B output 154B may read from the memory circuit 90 via the seventh transistor 116G. On the other hand, when the column decoder B 110B decodes a 0, the first port B output 154A may read from the memory circuit 90 via the sixth transistor 116F and the second port B output 154B may read from the memory circuit 90 via the eighth transistor 116H. Moreover, since either outputs from port A 101 or port B 103 may read from the memory circuit 90, the selection of via sites 56 in the depicted embodiment may configure the memory circuit 90 as a true dual-port memory. As such, the selection of via sites 56 in the depicted embodiment may configure the memory circuit 90 as a 2-bit width write true dual-port memory.

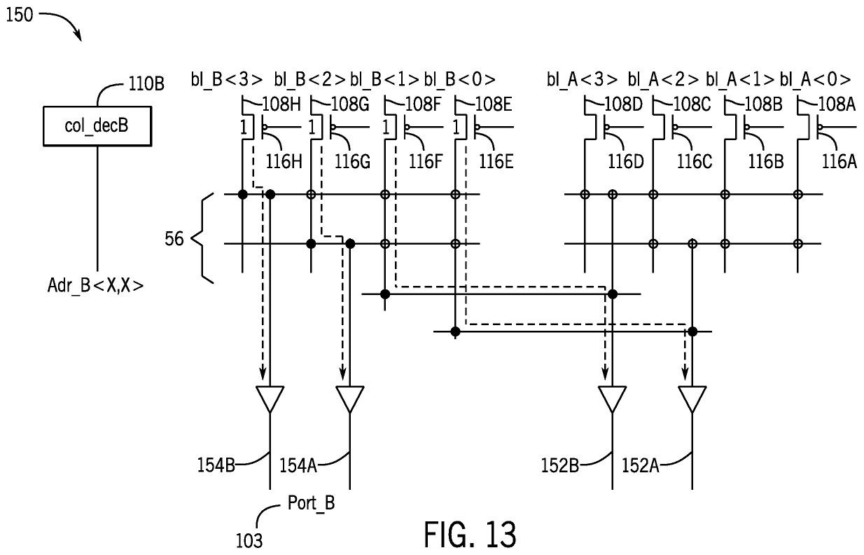

FIG. 13 depicts selection of via sites 56 of the via layer 150 to configure the via-configurable static random access memory circuit 90 of FIG. 7 as a 4-bit wide read simple dual-port memory. In the depicted embodiment, the column decoder B 110B may decode a value (e.g., column memory address) of 1. Upon decoding a 1, the bit lines 108 connected to the respective transistor 116 for the decoded value of 1 may enable an output to read data from the memory circuit 90 (e.g., via bit lines 108 connected to the respective transistor 116). As shown, the fifth transistor 116E, the sixth transistor 116F, the seventh transistor 116G, and the eighth transistor 116H, may correspond to a decoded value of 1. Thus, when the column decoder B 110B decodes a binary 1, four transistors may be enabled to read from the memory circuit 90. As such, the depicted embodiment may result in a 4-bit width write memory.

The outputs to read data may include a first port A output 152A, a second port A output 152B, a first port B output 154A, and a second port B output 154B. The selected via sites 56 (indicated by darkened via sites 56) create a via path (indicated by dashed arrows) that enables the a first port A output 152A to read via the fifth transistor 116E and the second port A output 152B to read via the sixth transistor 116F. Moreover, the selected via sites 56 create a path that enables the first port B output 154A to read via the sixth transistor 116F and the second port B output 154B to read via the eighth transistor 116H. Since the column decoder B 110B decodes one binary value at a time, such as binary 1, port B 103 may read four outputs at a time. That is, when the column decoder B 110B decodes a column memory address of 1, the port A outputs 152 and the port B outputs 154 may read from their respective transistor 116.

Moreover, since only transistors 116 receiving from port B 103 may read from the memory circuit 90, the selection of via sites 56 in the depicted embodiment may configure the memory circuit 90 as a simple dual-port memory. As such, the selection of via sites 56 in the depicted embodiment may configure the memory circuit 90 as a 4-bit width read simple dual-port memory (using four bit lines 108E-H). As such, different memory configurations may be implemented using the same single configurable memory circuit 90 that includes the via layer 100 or 150. Specifically, the particular memory configurations (e.g., memory width, depth, read and write capabilities) may be implemented by selecting specific via sites 56 of the via layer 100 or 150.

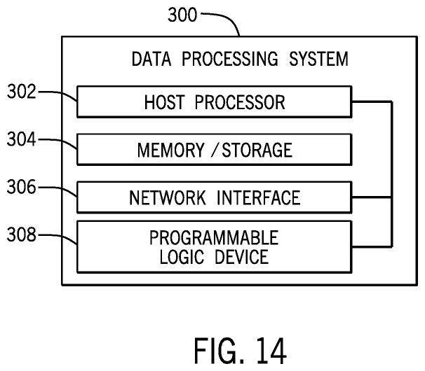

With the foregoing in mind, the integrated circuit device 12 may be a part of a data processing system or may be a component of a data processing system that may benefit from using the techniques discussed herein. For example, the integrated circuit device 12 may be a component of a data processing system 300, shown in FIG. 14. The data processing system 300 includes a host processor 302, memory and/or storage circuitry 304 (e.g., memory 22 of FIG. 1 and/or dual-port static random access memory circuit 90 of FIG. 7), and a network interface 306. The data processing system 300 may include more or fewer components (e.g., electronic display, user interface structures, application specific integrated circuits (ASICs)).

The host processor 302 may include any suitable processor, such as an INTEL® XEON® processor or a reduced-instruction processor (e.g., a reduced instruction set computer (RISC), an Advanced RISC Machine (ARM) processor) that may manage a data processing request for the data processing system 300 (e.g., to perform machine learning, video processing, voice recognition, image recognition, data compression, database search ranking, bioinformatics, network security pattern identification, spatial navigation, or the like). The memory and/or storage circuitry 304 may include random access memory (RAM), read-only memory (ROM), one or more hard drives, flash memory, or the like. The memory and/or storage circuitry 304 may be considered external memory to the integrated circuit device 12 and may hold data to be processed by the data processing system 300 and/or may be internal to the integrated circuit device 12. In some cases, the memory and/or storage circuitry 304 may also store configuration programs (e.g., configuration bitstream 18 of FIG. 1) for programming a programmable fabric of the integrated circuit device 12. The network interface 306 may permit the data processing system 300 to communicate with other electronic devices. The data processing system 300 may include several different packages or may be contained within a single package on a single package substrate.

In one example, the data processing system 300 may be part of a data center that processes a variety of different requests. For instance, the data processing system 300 may receive a data processing request via the network interface 306 to perform machine learning, video processing, voice recognition, image recognition, data compression, database search ranking, bioinformatics, network security pattern identification, spatial navigation, or some other specialized task. The host processor 302 may cause a programmable logic fabric of the integrated circuit device 12 to be programmed with a particular accelerator related to the requested task. For instance, the host processor 302 may instruct that configuration data (e.g., configuration bitstream 18 of FIG. 1) be stored on the memory and/or storage circuitry 304 or cached in sector-aligned memory of the integrated circuit device 12 to be programmed into the programmable logic fabric of the integrated circuit device 12. The configuration data may represent a circuit design for a particular accelerator function relevant to the requested task.

The processes and devices of this disclosure may be incorporated into any suitable circuit. For example, the processes and devices may be incorporated into numerous types of devices such as microprocessors or other integrated circuits. Exemplary integrated circuits include programmable array logic (PAL), programmable logic arrays (PLAs), field programmable logic arrays (FPLAs), electrically programmable logic devices (EPLDs), electrically erasable programmable logic devices (EEPLDs), logic cell arrays (LCAs), field programmable gate arrays (FPGAs), application specific standard products (ASSPs), application specific integrated circuits (ASICs), and microprocessors, just to name a few.

Moreover, while the method operations have been described in a specific order, it should be understood that other operations may be performed in between described operations, described operations may be adjusted so that they occur at slightly different times or described operations may be distributed in a system which allows the occurrence of the processing operations at various intervals associated with the processing, as long as the processing of overlying operations is performed as desired.

While the embodiments set forth in the present disclosure may be susceptible to various modifications and alternative forms, specific embodiments have been shown by way of example in the drawings and have been described in detail herein. However, it may be understood that the disclosure is not intended to be limited to the particular forms disclosed. The disclosure is to cover all modifications, equivalents, and alternatives falling within the spirit and scope of the disclosure as defined by the following appended claims. In addition, the techniques presented and claimed herein are referenced and applied to material objects and concrete examples of a practical nature that demonstrably improve the present technical field and, as such, are not abstract, intangible or purely theoretical. Further, if any claims appended to the end of this specification contain one or more elements designated as “means for [perform]ing [a function] . . . ” or “step for [perform]ing [a function] . . . ”, it is intended that such elements are to be interpreted under 35 U.S.C. 112(f). However, for any claims containing elements designated in any other manner, it is intended that such elements are not to be interpreted under 35 U.S.C. 112(f).

What is claimed is:

1. An integrated circuit device comprising:
a memory circuit; and
a via layer that, based on a via configuration of the via layer, causes the memory circuit of the integrated circuit device to function as:
a true dual-port memory circuit in a first via configuration; and
a simple dual-port memory circuit in a second via configuration.

2. The integrated circuit device of claim 1, wherein the memory circuit comprises an array of memory comprising a plurality of memory cells, a plurality of multiplexers, one or more row decoders, one or more column decoders, one or more bit lines, one or more word lines, or a combination thereof, and wherein at least one of the plurality of memory cells, the plurality of multiplexers, the one or more row decoders, the one or more column decoders, the one or more bit lines, the one or more word lines, or a combination thereof, forms part of the memory circuit in the first via configuration and does not form part of the memory circuit in the second via configuration.

3. The integrated circuit device of claim 2, wherein the one or more column decoders selects a first number of columns of the memory cells based on a first memory address for the first via configuration and selects a second number of columns of memory cells based on a second memory address for the second via configuration, wherein the first number of columns and the second number of columns are different

4. The integrated circuit device of claim 1, wherein the first via configuration comprises a first configuration of via sites in the via layer, the second via configuration comprises a second configuration of via sites in the via layer, and wherein the first via configuration of via sites and the second via configuration of via sites are different.

5. The integrated circuit device of claim 4, wherein the via sites configure the via layer, and wherein the configuring results in enabling and disabling each of the plurality of multiplexers that are connected to one or more bit lines based on the configuration of the via layer.

6. The integrated circuit device of claim 1, wherein the via layer comprises a plurality of vertical segments, a plurality of horizontal segments, or a combination thereof.

7. The integrated circuit device of claim 6, wherein the plurality of vertical segments, the plurality of horizontal segments, or a combination thereof, are connected using one or more jumpers.

8. The integrated circuit device of claim 1, wherein the via layer is associated with a single photomask.

9. The integrated circuit device of claim 1, wherein the true dual-port memory and the simple dual-port memory comprise a read port and a write port.

10. A method of manufacturing an integrated circuit comprising:
forming memory circuitry using a first one or more masks; and
forming vias using a second one or more masks to produce one of a plurality of via configurations, wherein a first via configuration of the plurality of via configurations causes a portion of the memory circuitry to operate as a first bit width memory circuit, wherein a second via configuration of the plurality of via configurations causes a portion of the memory circuitry to operate as a second bit width memory circuit, and wherein the first bit width and the second bit width are different.

11. The method of claim 10, comprising a third via configuration of the plurality of via configurations that causes the portion of the memory circuitry to operate as a read memory circuit or a write memory circuit.

12. The method of claim 10, wherein the memory circuitry, when used with any of the first via configuration and the second via configuration, comprises at least one redundant component, wherein the redundant component is a common component to a memory circuit resulting from the first via configuration and the memory circuit resulting from the second via configuration.

13. The method of claim 10, wherein the second one or more masks for the vias replaces at least one or more masks associated with the first bit width memory circuit, the second bit width memory circuit, or a combination thereof.

14. A configurable circuit, comprising:
a memory circuit comprising an array of memory cells, a plurality of multiplexers, one or more row decoders, one or more column decoders, one or more bit lines, one or more word lines, or a combination thereof; and
a plurality of vias connected to at least a portion of the memory circuit to implement:
a true dual-port memory circuit in a first via configuration;
a simple dual-port memory circuit in a second via configuration;
a first bit width memory circuit in a third via configuration; and
a second bit width memory circuit in a fourth configuration.

15. The configurable circuit of claim 14, where the plurality of vias connect each of the plurality of multiplexers to the one or more bit lines.

16. The configurable circuit of claim 14, wherein the first bit width comprises 20 bits and the second bit width comprises 80 bits.

17. The configurable circuit of claim 14, wherein the plurality of multiplexers are associated with a respective bit line connected to a memory cell of the array of memory cells.

18. The configurable circuit of claim 14, wherein the plurality of multiplexers are enabled by being set to a binary 1 via the one or more column decoders.

19. The configurable circuit of claim 14, wherein the plurality of vias connected to at least a portion of the memory circuit implements a fifth configuration, wherein the fifth configuration causes the portion of the memory circuit to operate as a read memory circuit or a write memory circuit.

20. The configurable circuit of claim 19, wherein a portion of the memory circuit operates as the read memory circuit and another portion of the memory circuit operates as the write memory circuit concurrently.
